(19) United States
(12) Patent Application Publication
(10) Pub. No.: US 2019/0040250 A1
(43) Pub. Date: Feb. 7, 2019

(54) EPOXY RESIN SYSTEM, USE OF AN EPOXY RESIN SYSTEM, OPTOELECTRONIC DEVICE, AND PROCESS FOR PRODUCING AN EPOXY RESIN SYSTEM

(71) Applicant: OSRAM Opto Semiconductors GmbH, Regensburg (DE)

(72) Inventors: Klaus HOEHN, Forchheim (DE); Christina KEITH, Neutraubling (DE)

(21) Appl. No.: 16/076,302

(22) PCT Filed: Feb. 13, 2017
(86) PCT No.: PCT/EP2017/053155

§ 371 Date: Aug. 7, 2018

(30) Foreign Application Priority Data
Feb. 16, 2016 (DE) 10 2016 102 685.9

(51) Int. Cl. C08L 63/00; C08K 3/013; H01L 33/50

(52) U.S. Cl. CPC C08L 63/00; C08K 3/013; C08K 2003/2227; H01L 33/505; H01L 33/501

(57) ABSTRACT

The invention relates to an epoxy resin system comprising at least one inorganic filler (F) which has an upper grain size (dₘₐₓ) of a maximum of 30 μm and is an oxide or nitride of a metal or a semimetal, at least one cycloaliphatic epoxy resin, polyvinyl butyrate, at least one cationic accelerator, and wherein the epoxy resin system is a one-component system for thin-walled structural elements.

The invention relates to an epoxy resin system, in particular a one-component epoxy resin system. Furthermore, the invention relates to the use of an epoxy resin system. Furthermore, the invention relates to an optoelectronic device. Furthermore, the invention relates to a process for producing an epoxy resin system.

In electronic devices, for example in optoelectronic devices such as light-emitting diodes and light modules, epoxy resins, thermoplastics and silicones are often used as mounting and housing materials, casting resins and/or as matrix materials for light conversion elements, reflection layers and optical filters, for example, as well as lens materials. Today, high-performance polymers, such as glass fiber reinforced thermoplastics, mainly based on polyphthalamide, silicones, moldable epoxy resin compounds (EMC) have proven their worth as housing materials. However, due to the processing and the size of the fillers used, it is not possible to produce housings with wall thicknesses of considerably less than 200 μm with these materials. Furthermore, these materials can be used under clean room conditions only to a limited extent because there are concerns about additives and processing aids containing siloxane and silicone.

An object to be solved by the invention is to provide an epoxy resin system with improved properties. In particular, the epoxy resin system can be used to provide or manufacture housings for optoelectronic devices with wall thicknesses of up to 80 μm. Furthermore, the epoxy resin system according to the invention can be used for high operating temperatures. A further object of the invention is to provide an optoelectronic device that has an epoxy resin system with the improved properties. Another object of the invention is to provide a cost-effective process for producing the epoxy resin system.

These objects are solved by an epoxy resin system according to independent claim 1. Advantageous embodiments and further developments of the invention are subject-matter of the dependent claims. Furthermore, these objects are solved by the use of an epoxy resin system according to claim 13. Furthermore, these objects are solved by an optoelectronic device according to claim 14. Furthermore, these objects are solved by a process for producing an epoxy resin system according to claim 15.

In at least one embodiment, the epoxy resin system comprises or consists of at least one inorganic filler, at least one cycloaliphatic epoxy resin, a polyvinyl butyrate and at least one cationic accelerator. The inorganic filler is particularly an oxide of a metal or semi-metal or a nitride of a metal or semi-metal. In particular, the inorganic filler has an upper grain size (dₘₐₓ) of not more than 30 μm. The epoxy resin system is in particular a one-component system.

Epoxy resin is usually provided as a two-component system to be mixed by the user ready for use. The so-called “A-component” usually contains the epoxy resin, the so-called “B-component” the hardener, which is added to the resin in a predetermined mixing ratio. One-component system means here and in the following that the epoxy resin system is reactive and thermally cures and has no B-component. One-component systems are delivered ready for use and can be stored. A B-component is especially an organic substance such as a carboxylic anhydride. A carboxylic anhydride of the B-component together with an accelerator usually cross-links the A-component (corresponds to formulated epoxy resin). This cross-linking produces a duromer epoxy resin molding material. The carboxylic anhydride together with an accelerator can be described as a hardener.

According to at least one embodiment, the epoxy resin system comprises at least one inorganic filler or a mixture of several inorganic fillers. The inorganic filler is selected from the group comprising an oxide of a metal, an oxide of a semimetal, a nitride of a metal and a nitride of a semimetal. In particular, the inorganic filler is selected from the group comprising silicon dioxide, titanium dioxide, aluminium oxide and zirconium oxide.

In particular, silicon dioxide, which is preferably amorphous, is used as an inorganic filler. Silicon dioxide with the CAS number (Chemical Abstracts Service) 60676-86-0 is preferred.

According to at least one embodiment, the inorganic filler has a content between 50% by weight inclusive and 85% by weight inclusive, preferably between 60% by weight inclusive and 80% by weight inclusive, based on the total weight of the epoxy resin system.

According to at least one embodiment, the inorganic filler has a specific surface area of at least 2 g/m² and at most 20 g/m², in particular between 2 g/m² inclusive and 10 g/m² inclusive, preferably between 2 g/m² inclusive and 8 g/m² inclusive, particularly preferably between 2.2 g/m² inclusive and 5.5 g/m² inclusive.

In addition or alternatively, the inorganic filler may have a grain size value d₅₀ of at least 0.5 μm and/or a maximum of 20 μm. In particular, the inorganic filler has a grain size value d₅₀ between 2 μm and 10 μm, preferably between 2.5 μm and 4.4 μm.

Alternatively or additionally, the inorganic filler can have an upper grain size dₘₐₓ of a maximum of 30 μm or 25 μm or 20 μm, in particular of a maximum of 16 μm, for example 12 μm.

The specific surface area can be determined by means of BET isotherm. Unless otherwise stated, the grain size value d₅₀ is defined below as the value d₅₀, which is defined in such a way that 50% of the material is below and/or 50% of the material is above this size or diameter in relation to the volume fraction. The grain size value can be determined by dynamic light scattering (DLS). The term upper grain size dₘₐₓ is used here and in the following to describe an inorganic filler filled in as a particle, which has a maximum diameter as upper grain size. In other words, according to DLS (Dynamic Light Scattering) there are no inorganic fillers present in the epoxy resin system that are larger than the upper grain size.

According to at least one embodiment, the inorganic filler has a specific surface area of at least 2 g/m² and at most 20 g/m² and a grain size value d₅₀ of at most 20 μm and an upper grain size dₘₐₓ of at most 30 μm.

According to at least one embodiment, the epoxy resin system comprises at least one cycloaliphatic epoxy resin. An epoxy resin system with the CAS number 2386-87-0 is preferably used as the cycloaliphatic epoxy resin system.

According to at least one embodiment, the cycloaliphatic epoxy resin contains at least two epoxy functions.

According to at least one embodiment, the cycloaliphatic epoxy resin is selected from a group of compounds comprising 3,4-epoxycyclohexyl-methyl-3,4-epoxycyclohexyl carboxylate and poly [(2-oxiranyl)-1,2-cyclohexanediol]-2-ethyl-2-(hydroxymethyl)-1,3-propanediol ether. Preferably the cycloaliphatic epoxy resin is 3,4-epoxycyclohexyl-methyl-3,4-epoxycyclohexyl carboxylate or (bis(epoxycyclohexyl)methyl carboxylate) having the following structure (formula I):

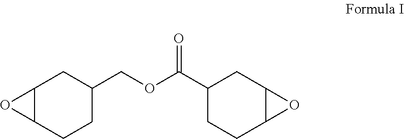 [SMILES: O=C(OCC1CCC2OC2C1)C1CCC2OC2C1]

In one embodiment, the epoxy resin system does not contain any aromatic epoxy resin. Preferably, the epoxy resin system does not contain an aromatic compound. Aromatic compound means that the corresponding compound contains at least one aromatic ring. Because the epoxy resin system has no aromatic epoxy resin, preferably no aromatic compound, the epoxy resin system is significantly more light-stable. This means that it is less susceptible to yellowing when exposed to radiation, for example in an optoelectronic device, such as a light-emitting diode (LED). Compared to epoxy resins based on bisphenol A, the light stability is increased.

According to at least one embodiment, the content of the cycloaliphatic epoxy resin is between 3% by weight inclusive and 50% by weight inclusive, preferably between 3% and 40% by weight, based on the total weight of the epoxy resin system.

According to at least one embodiment, titanium dioxide, TiO₂, is used as the inorganic filler. In particular, rutile-type titanium dioxide is used. In particular, the titanium dioxide has a CAS number 13463-67-7, EINECS 236-675-5, color index CI77891 and/or pigment white 6 (77891).

According to at least one embodiment of the epoxy resin system, it contains a polyvinyl butyrate as a polymer additive. In particular, polyvinyl butyrate with CAS number 68648-78-2 is used.

Polyvinyl butyrate are available with different molecular weights and different degrees of acetalization (formula III). The epoxy resin system can comprise several polyvinyl butyrate with different molecular weights and/or different degrees of acetalization.

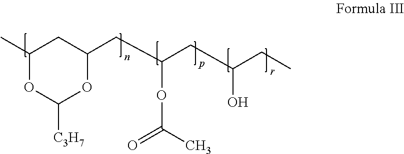

The arrangement of the acetal, acetyl and hydroxy groups shown in the structural unit of formula III is not to be regarded as fixed. Rather, a statistical distribution or arrangement of the acetal, acetyl and hydroxy groups may be present. For example, a structural section could look like this (formula V):

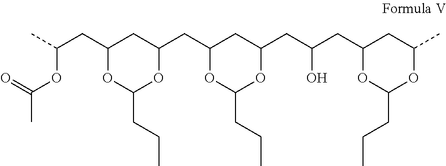

Polyvinyl butyrate shows sufficient solubility in the cycloaliphatic epoxy resin.

According to at least one embodiment, the polyvinyl butyrate has gas transition temperatures of 63 to 84° C. At room temperature, the polyvinyl butyrate is present as a solid.

In accordance with at least one embodiment, the polyvinyl butyrate has an average molecular weight of from 10,000 g/mol to 80,000 g/mol, preferably from 20,000 g/mol to 70000 g/mol, for example 30,000 g/mol or 600,000 g/mol. With the use of polyvinyl butyrate having such average molecular weights, epoxy resin systems are available which have reduced brittleness, lower susceptibility to cracking, and higher bond strength over conventional cycloaliphatic epoxy based epoxy resins.

In accordance with at least one embodiment, the polyvinyl butyrate is selected from a group consisting of PVB B 30 T, PVB B 30 M, PVB B 30 H, PVB B 30 S, PVB B 30 HH, PVB B 60 T, PVB B 60 M, PVB B 60 H, PVB B 60 S, PVB B 60 HH and combinations thereof. The compounds are different polyvinyl butyrate types from Kuraray. Here, the number “30” or “60” stands for the average molecular weight, which is about 30,000 g/mol or 60,000 g/mol. The suffixes “T, M, H, S and HH” are an indication of the degree of acetalization which increases in that order and thus “T” stands for a low and “HH” for the highest possible degree of acetalization.

Due to the amount and type of polyvinyl butyrate used, the elasticizing and thermomechanical properties, the adhesion and moisture absorption behavior as well as the resistance to environmental influences of the epoxy resin system can be controlled in a targeted manner.

According to at least one embodiment of the epoxy resin system, the polyvinyl butyrate has a content between 0.1% by weight inclusive and 10% by weight inclusive, preferably between 0.1% by weight and 3% by weight inclusive, based on the total weight of the epoxy resin system.

According to at least one embodiment of the epoxy resin system, the polyvinyl butyrate has a content between 0.1% by weight inclusive and 10% by weight inclusive, preferably between 0.1% by weight and 3% by weight inclusive, based on the total weight of the epoxy resin system.

The epoxy resin system has a cationic accelerator. The cationic accelerator may be present in a content between 0.1% by weight inclusive and 3% by weight inclusive, preferably between 0.1% by weight inclusive and 2% by weight inclusive, based on the total weight of the epoxy resin system. The accelerator cures the epoxy resin system when exposed to temperature by cross-linking the epoxy functions according to a cationic homopolymerization mechanism.

According to at least one embodiment, the cationic accelerator is a halonium and/or sulfonium salt, preferably a thiolanium salt. The cationic accelerator may contain complex anions such as BF₄⁻, PF₆⁻, AsF₆⁻ and/or SbF₆⁻. In particular, the cationic accelerator is an S-benzylthiolanium hexafluoroantimonate having the following structural formula:

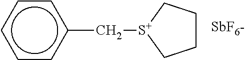

The cationic accelerator can be obtained from Sigma Aldrich as PI 55.

According to at least one embodiment of the epoxy resin system, it also comprises an alcohol. The alcohol may be polyhydric. The alcohol can be an aliphatic or cycloaliphatic alcohol. The alcohol may be selected from the group consisting of ethanol, 1,2-propanediol, 1,4-butanediol, 1,6-hexanediol, cyclohexanedimethanol, 2-ethyl-2-hydroxymethyl, 1,3-propanediol, diethylene glycol, triethylene glycol, polyethylene glycol, polypropylene glycol, dipropylene glycol, tripolyethylene glycol, monoalkyl ether, glycerol and isosorbite. In particular, the alcohol may be 1,2-propanediol, butanediol or trimethylolpropane. The rheological, mechanical and thermomechanical properties as well as the wetting and flow behavior of the epoxy resin system can be adapted to the desired application form of the epoxy resin system by adding the alcohol.

According to at least one embodiment, the epoxy resin system contains between 0.1% by weight inclusive or 3% by weight inclusive and 3% by weight or 10% by weight inclusive, preferably between 0.1% by weight inclusive and 5% by weight inclusive, based on the total weight of the epoxy resin system.

Alternatively or additionally, the epoxy resin system may contain further epoxy resins. Another epoxy resin can be, for example, epoxy phenol novolac and epoxy resol novalac. In particular, epoxy phenol novolac with CAS number 28064-14-4 is used. Epoxy phenol novolac may have the following structural formula with n preferably between 0.2 and 1.8:

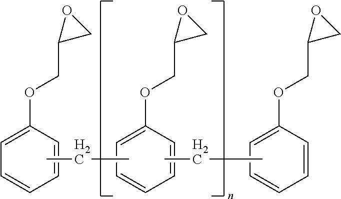

According to at least one embodiment, the other epoxy resins have a content of the total weight of the epoxy resin system between 0% by weight inclusive and 10% by weight inclusive, preferably between 0% by weight inclusive and 5% by weight inclusive. The epoxy phenol novolac resins are known to experts and are therefore not explained here. Epoxy phenol novolac resins are available from DOW, for example, as DEN-types. Other epoxy resins are available, for example, from Huntsman with the type designations EPN and ECN.

In at least one embodiment, the epoxy resin system comprises other materials selected from the group consisting of reactive diluents, silane coupling agents, carbon black, titanium dioxide pigment, fumed silica, CaCO₃, deaerators, degassing agents, levelling agents, release agents, light stabilizer, organic dyes, brighteners and fluorescent pigments for LED conversion. Furthermore, the epoxy resin system can contain pigments such as carbon black, titanium dioxide, aluminum oxide, calcium fluoride and/or phosphors.

The reactive diluent may comprise an epoxy resin or an epoxy resin compound with one or two epoxy functions. In particular, the reactive diluent is an aliphatic epoxy compound. The reactive diluent can influence the glass transition temperature and the viscosity of the epoxy resin system. For example, a glycidyl ether, such as hexadiol diglycidyl ether with CAS number 16096-31-4, can be chosen as a reactive diluent.

In particular, the reactive diluent has a content between 0% by weight and 10% by weight inclusive, preferably between 0% by weight and 5% by weight inclusive, based on the total weight of the epoxy resin system.

According to at least one embodiment, the epoxy resin system can have a silane coupling agent. The silane coupling agent may contain between 0% by weight inclusive and 5% by weight inclusive, preferably between 0% by weight inclusive and 3% by weight inclusive, based on the total weight of the epoxy resin system.

According to at least one embodiment, the epoxy resin system can comprise pigment carbon black. In particular, the content of pigment carbon black is between 0% by weight and 2% by weight inclusive, in particular between 0% by weight and 1% by weight inclusive based on the total weight of the epoxy resin system.

According to at least one embodiment, the epoxy resin system contains titanium dioxide pigment. In particular, the content of titanium dioxide pigment is between 0% by weight inclusive and 20% by weight inclusive, preferably between 0% by weight inclusive and 10% by weight inclusive, based on the total weight of the epoxy resin system.

According to at least one embodiment, the epoxy resin system contains fumed silica, in particular with a content between 0% by weight and 3% by weight inclusive, preferably between 0% by weight and 2% by weight inclusive, based on the total weight of the epoxy resin system. Aerosil R202 or Aerosil 200 can be used as pyrogenic silicas.

According to at least one embodiment, the epoxy resin system can have a silicone-free deaerator and/or a degassing agent. The deaerators and/or degassing agent may contain organic fluorine compounds, esters or acrylates. For example, BYK-A555 can be used as a deaerator and/or degassing agent. Deaerators and/or a degassing agent are available from Evonik and BYK-Chemie as commercial products.

In particular, the deaerator and/or degassing agent has a content of between 0% by weight and 1% by weight inclusive, in particular between 0% by weight and 0.5% by weight inclusive, based on the total weight of the epoxy resin system.

According to at least one embodiment, the epoxy resin system has a levelling agent. For example, products from the Modaflour series can be used as levelling agents. In particular, the levelling agent has a content of between 0% by weight and 1% by weight inclusive, preferably between 0% by weight and 0.5% by weight inclusive, based on the total weight of the epoxy resin system.

According to at least one embodiment, the epoxy resin system contains release agents. Waxes of long-chain carboxylic acids can preferably be used as release agents. A carbon chain or a carboxylic acid with 12 to 30 carbon atoms is understood as long chain. For example, commercially available carnauba waxes or the hydrocarbon wax Baerolub L-KK from Baerloher can be used as release agents. In particular, the release agent contains between 0% by weight and 1% by weight inclusive, preferably between 0% by weight and 0.5% by weight inclusive, based on the total weight of the epoxy resin system.

According to at least one embodiment, the epoxy resin system contains one or more light stabilizers. Products from the series with the trade names Tinnvin, Irgonor, Irgafos, Tinnvin234, Tinnvin123, Irgafos163 or IrganoxMD1024 can be used as light stabilizers and/or stabilizers. In particular, the light stabilizer has a content between 0% by weight and 1% by weight inclusive, preferably between 0% by weight and 0.5% by weight inclusive, based on the total weight of the epoxy resin system.

According to at least one embodiment, the epoxy resin system may contain optical brighteners and/or dyes. For example, the epoxy resin system may contain antrachinone dyes.

In particular, the organic dye and/or brightener has a content of between 0% by weight and 1% by weight inclusive, preferably between 0% by weight and 0.5% by weight inclusive, based on the total weight of the epoxy resin system.

For example, 1,3-di-tertiary butyl-4-hydroxyphenol can be used as a light stabilizer. Light stabilizers are also available under the trade name Tinuvin.

According to at least one embodiment, the epoxy resin system contains fluorescent pigments. Rare earth doped garnets, rare earth doped alkaline earth sulfides, rare earth doped thiogallates, rare earth doped aluminates, rare earth doped silicates such as orthosilicates or chlorosilicates, rare earth doped alkaline earth silicon nitrides, rare earth doped oxynitrides, rare earth doped aluminum oxynitrides, rare earth doped silicon nitrides and/or sialones can be selected as phosphors. Garnets such as yttrium alumininium oxide (YAG), yttrium gadolinium aluminium oxide, luthetium aluminium oxide (LuAG), gallium aluminium oxide and therbium aluminium oxide (TAG) can be used as phosphors. The phosphors can be doped with cerium ions, europium ions, terbium ions, praseodymium ions, samarium ions or manganese ions. In particular, the phosphor is designed to convert radiation of a certain wavelength into radiation of another, especially longer wavelength. These phosphors can also be referred to as converter materials. Preferably the fluorescent pigments or phosphors have a content between 0 and 30% by weight inclusive, preferably between 0% and 20% by weight inclusive, based on the total weight of the epoxy resin system.

In particular, the components silane coupling agent, fumed silica, deaerator, degassing agent, levelling agent, release agent, light stabilizer, organic dyes and/or brightener of the epoxy resin composition can also be described as resin additives. For fine adjustment to the respective specific application and use, the content of these resin additives in total is a maximum of 5% by weight.

According to at least one embodiment, the epoxy resin system comprises or consists of a cycloaliphatic epoxy resin, preferably with a content of 85% by weight, an epoxy phenol novolac with a content of preferably 10% by weight, an alcohol, preferably with a content of 1% by weight, polyvinyl butyrate, preferably with a content of 3% by weight, and a cationic accelerator, preferably with a content of 1% by weight. In particular, the epoxy resin system with such a composition has a refractive index of 1.5065 at 24° C. and a viscosity of 2900 mPas at 25° C.

In at least one embodiment, the epoxy resin system comprises or consists of a composition of a cycloaliphatic epoxy resin, preferably with a content of 95.5% by weight, an alcohol, preferably with a content of 1% by weight, a polyvinyl butyrate, preferably with a content of 2% by weight, and a cationic acceleration, preferably with a content of 1.5% by weight. Such an epoxy resin composition has a refractive index of 1.4960 at 25° C. and a viscosity of 1240 mPas at 25° C.

According to at least one embodiment, the epoxy resin composition comprises a cycloaliphatic epoxy resin, preferably with a content of 96.8% by weight, an alcohol, preferably with a content of 1% by weight, polyvinyl butyrate, preferably with a content of 1% by weight, and a cationic accelerator, preferably with a content of 1.2% by weight. The refractive index of such an epoxy resin composition is 1.4974 at 22° C. and viscosity is 609 mPas at 25° C.

The production of the epoxy resin system and/or the mixing in of resin additives or additives, such as pigments, can be carried out according to methods known to a skilled artisan. In a second process step, the inorganic filler, preferably amorphous silicon dioxide, and optionally pigments such as carbon black, titanium dioxide, aluminum oxide, calcium fluoride and/or phosphors are preferably added. Thermal curing can take place at a temperature above 120° C. using a cationic mechanism with a thiolanium salt as a cationic accelerator, which may comprise the complex anions mentioned above.

The inventors have recognized that the epoxy resin system described above has advantageous properties and is a one-component system. The epoxy resin composition can be stored at room temperature or especially in the refrigerator.

According to at least one embodiment, the epoxy resin system is storage stable at a temperature between 4° C. and 10° C. inclusive, in particular for at least six months.

According to at least one embodiment, the epoxy resin system is anhydride-free, silicone-free and/or siloxane-free. In particular, the epoxy resin system can be formulated silicone- and siloxane-free for critical cleanroom applications.

The epoxy resin system can have a low coefficient of thermal expansion. For example, with a filling degree of 65% by weight of inorganic filler, the epoxy resin system can have a thermal expansion coefficient (TMA, CTE, coefficient of thermal expansion) of 20 ppm/K.

The epoxy resin system can have a high glass transition temperature, especially a glass transition temperature of >200° C. (DMA).

The epoxy resin system can have a high short-term temperature resistance. This means that the epoxy resin system has a stability against the high temperatures of usually 260° C., in some cases up to 325° C., which are briefly reached during soldering. The weight loss of the epoxy resin masses at 300° C. with synthetic air as TGA medium (TGA, thermogravimetric analysis) with a heating rate of 10 K/min is <1%.

The epoxy resin system can be used in particular as a black and/or white adjusted surface with good light stability for optical applications.

According to at least one version, the epoxy resin system has a chlorine content of <100 ppm, especially <50 ppm, preferably <20 ppm.

In particular, the epoxy resin system has a low EHS (Environmental, Health and Safety) risk potential and can therefore be classified as less critical for people in occupational safety and the environment.

The epoxy resin system can be used in particular for further applications due to a wide rheology window. For example, the epoxy resin system can be used as housing material, mounting material, casting resin, matrix material for light conversion elements, reflection layers and optical filters or as lens material. In particular, the epoxy resin system can be used for thin-walled housings for optoelectronic devices, especially with wall thicknesses of <80 μm. Furthermore, the advantage of the epoxy resin system is that the production costs are lower compared to silicones and epoxy mold compounds.

The use of an epoxy resin system is also indicated. The above-mentioned epoxy resin system is preferably used for an optoelectronic device.

According to at least one design, the optoelectronic device is selected from a group comprising a luminescent diode, a photodiode, a phototransistor, a photo-array, an optical coupler, an SMD device and an SMD-capable device. The optoelectronic device can be used, for example, in the automotive sector and/or for outdoor applications.

An optoelectronic device is also specified. Preferably, the optoelectronic device has the epoxy resin system described above. All definitions and embodiments for the optoelectronic device apply as specified above for the epoxy resin and vice versa.

According to at least one embodiment, the optoelectronic device has an epoxy resin system. In particular, the epoxy resin system is shaped as a housing, reflection element, casting, conversion element and/or substrate.

The epoxy resin system is preferably shaped as the housing of the optoelectronic device. The housing may have a recess. A layer sequence or a semiconductor layer sequence of a semiconductor chip can be inserted in this recess. The semiconductor layer sequence of the semiconductor chip is preferably based on a III-V compound semiconductor material. The semiconductor material is preferably a nitride compound semiconductor material, such as AlₙIn₁₋ₙ₋ₘGaₘN, InGaN, GaN or also a phosphide-compound semiconductor material, such as

AlₙIn₁₋ₙ₋ₘGaₘP, where 0≤n≤is 1, 0≤m≤1 and n+m≤1, respectively. The semiconductor material can also be AlₓGa₁₋ₓAs with 0≤x≤1. The semiconductor layer sequence can contain dopants and additional components. For simplicity's sake, however, only the essential components of the crystal lattice of the semiconductor layer sequence, i.e. Al, As, Ga, In, N or P, are given, even if these can be partially replaced and/or supplemented by small amounts of other substances.

According to at least one embodiment, the epoxy resin system is designed as a reflection element. The epoxy resin system can additionally contain scattering particles such as calcium fluoride and/or titanium dioxide.

According to at least one embodiment, the epoxy resin system is designed as a casting compound. The casting may additionally contain luminescent materials that are designed to convert the radiation emitted by a semiconductor layer sequence into radiation with a different wavelength. The phosphors can be homogeneously embedded as particles in the epoxy resin system.

According to at least one embodiment, the epoxy resin system is designed as a substrate. This substrate can be equipped with a semiconductor layer sequence for emitting radiation.

A process for the production of an epoxy resin system is also specified. The epoxy resin system described above is preferably produced using this process. All designs and definitions of the epoxy resin system also apply to the process for producing an epoxy resin system and vice versa.

According to at least one embodiment, the procedure comprises the following procedural steps:

A) providing a cycloaliphatic epoxy resin,
B) adding of polybuytl butyrate at a temperature between 50° C. inclusive and 80° C. inclusive,
C) adding a cationic accelerator at a maximum temperature of 45° C. to form a matrix,
D) mixing the matrix produced according to step C) with at least one inorganic filler which is an oxide or nitride of a metal or semimetal and
E) curing of the mixture produced in accordance with step D) at a temperature between 120° C. and 190° C. inclusive.

In particular, the viscosity of the liquid resin formulation is set as low as possible so that as much inorganic filler as possible can be achieved for the lowest possible thermal expansion (CTE), high mechanical rigidity and high thermal stability. On the one hand, the inorganic filler should be as fine as possible, but on the other hand, it should not be too small, as otherwise it will not be possible to achieve sufficiently high filling level during production. It can also inhibit resin application due to excessive viscosity or thixotropy. High filling level are desirable for the highest possible reliability and stability of the components. With the inorganic fillers present, in particular spherical amorphous silicon dioxide filler, with grain sizes d₅₀ between 0.5 μm or 2 μm and 10 μm or 20 μm, preferably between 2 and 8 μm and an upper grain size of 30 μm, preferably 20 μm, high filling level of up to 80% by weight, preferably up to 75% by weight, can be achieved. The filler quantities in the resin are in particular 50 to 85% by weight, preferably 60 to 80% by weight. Depending on the level of filling, the application can be carried out by dispensing, jetting or molding (compression molding). Thus an epoxy resin system can be produced as housing material, as cover layer, as reflection layer, as underfiller, as conversion element.

Curing in step E) can preferably take place between 120° C. and 190° C., preferably between 140° C. and 180° C., for example two hours at 160° C.

A new one-component epoxy resin system can be provided that meets the technical LED requirements with regard to cost, processing and innovative thin-walled LED form. Dynamic-mechanical investigations on the cured molding materials show a glass transition temperature of >200° C. (DMA), exhibit good mechanical brittleness behavior for reliable LED products and have a thermal expansion coefficient of 20 ppm/K (TMA) at a filling level of 75% by weight.

Further advantages, advantageous embodiments and further developments result from the examples described below in connection with the figures.

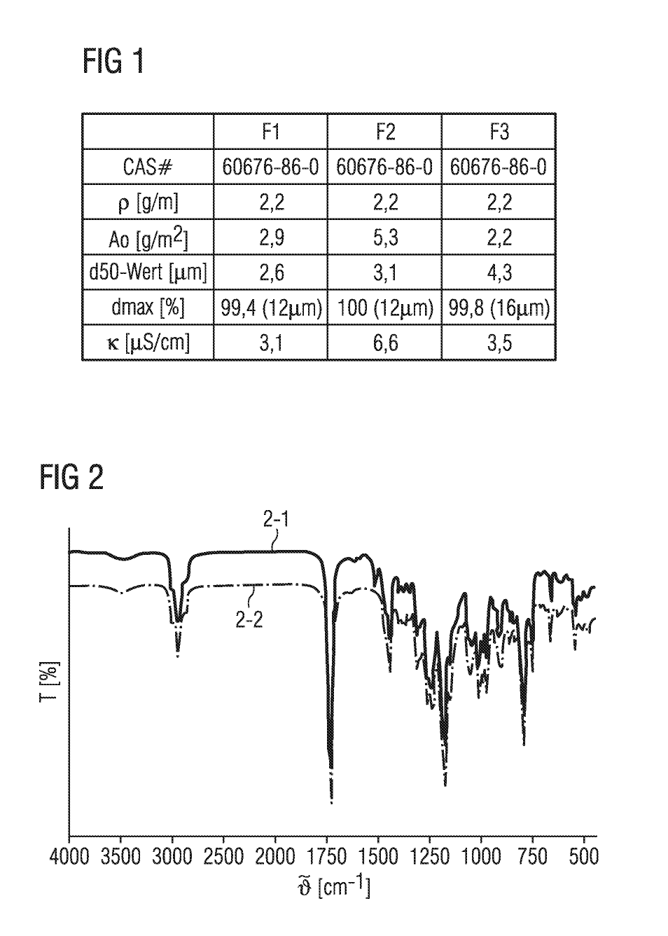

FIG. 1 shows fillers according to an embodiment,

FIG. 2 shows a FTIR spectrum of epoxy resin systems according to an embodiment,

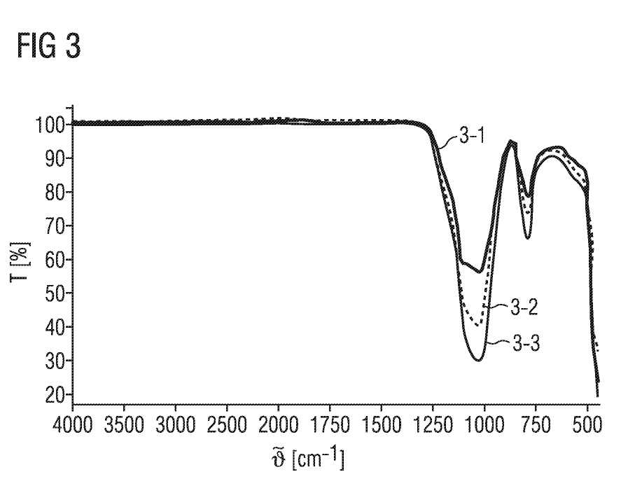

FIG. 3 shows a FTIR spectrum of fillers according to an embodiment,

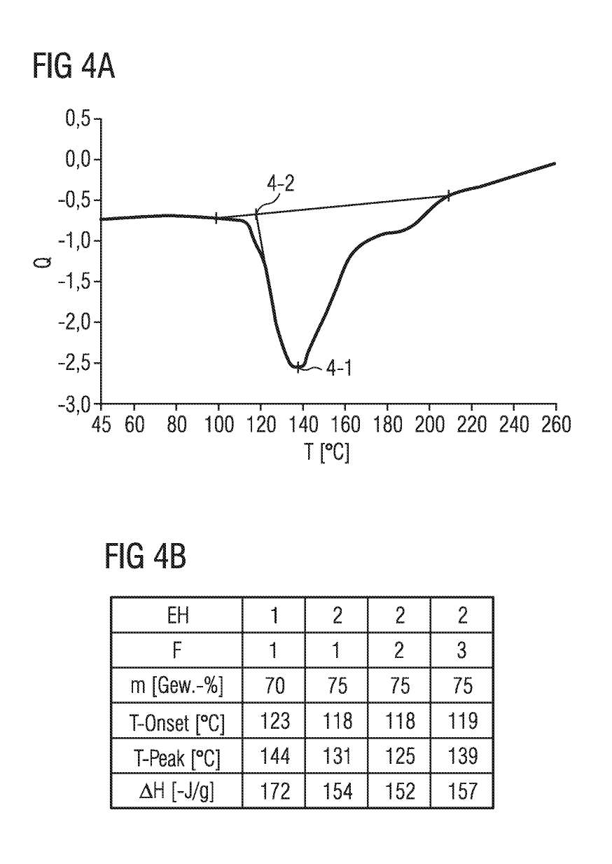

FIGS. 4A and 4B show a DSC curve and DSC characteristics of epoxy resin systems according to an embodiment,

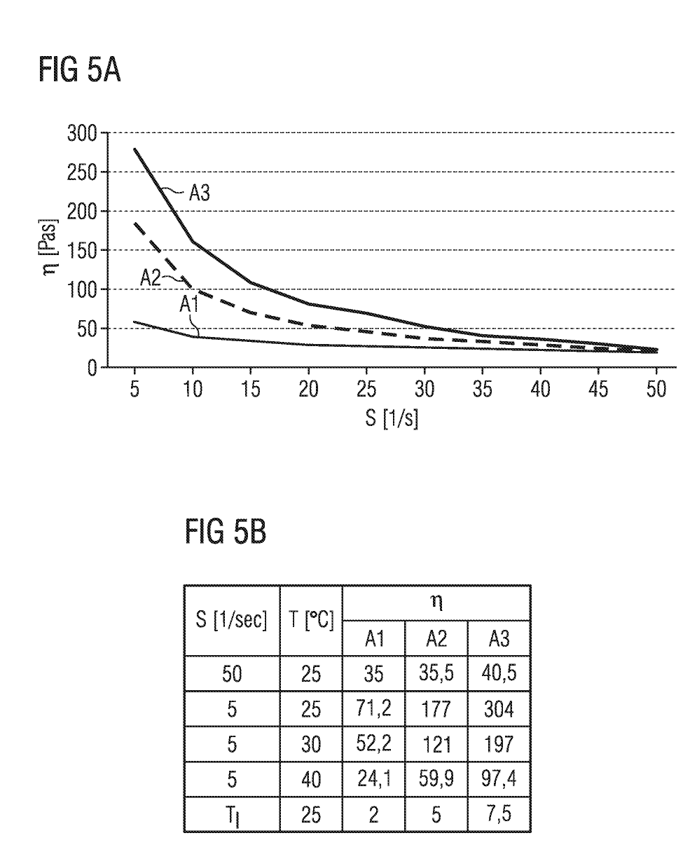

FIGS. 5A to 7B each contain rheology measurements or data of epoxy resin systems according to an embodiment,

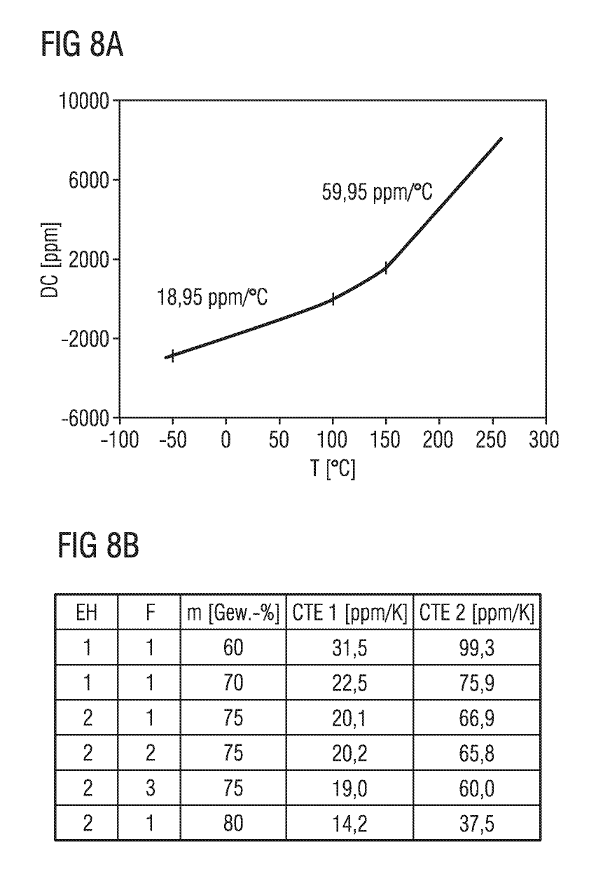

FIGS. 8A and 8B show TMA measurements of epoxy resin systems according to an embodiment,

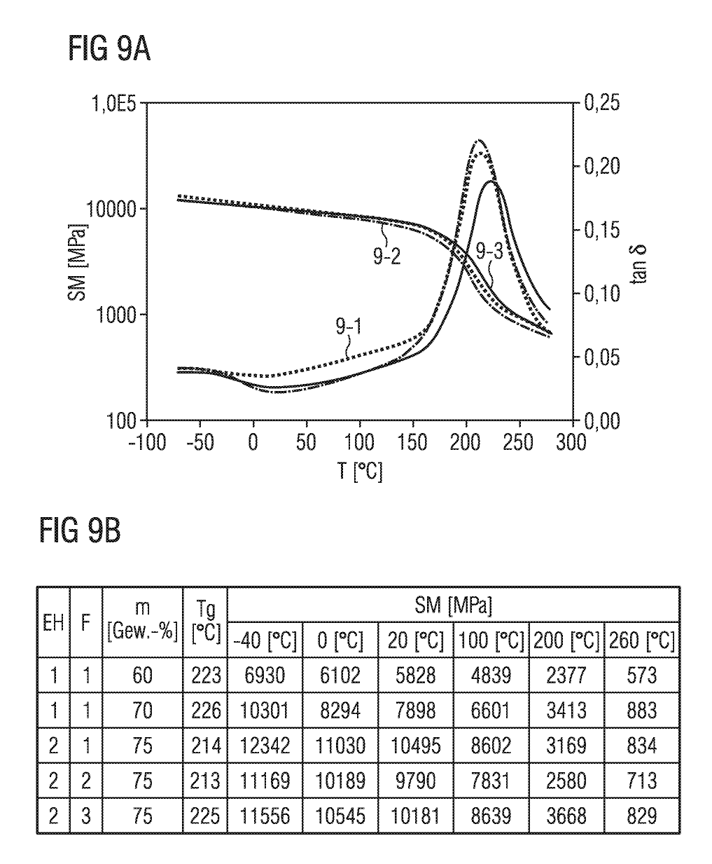

FIGS. 9A and 9B DMA show measurements of epoxy resin systems according to an embodiment,

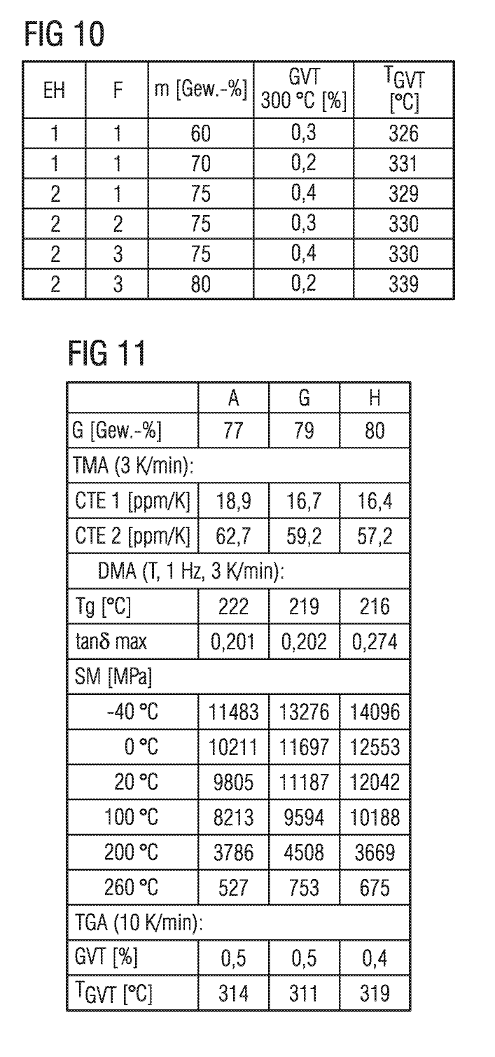

FIG. 10 shows TGA measurements of epoxy resin systems according to an embodiment,

FIG. 11 shows Physical data of epoxy resin systems according to an embodiment, and

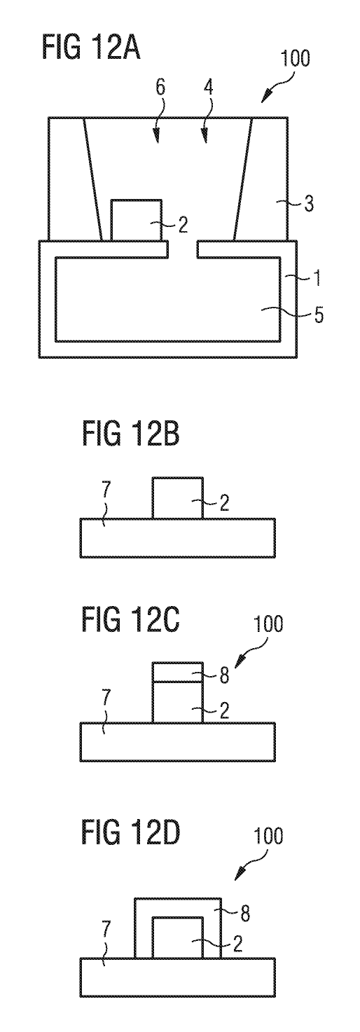

FIGS. 12A to 12D each contain an optoelectronic device according to an embodiment.

In the examples and figures, similar, identical elements or elements having the same effect can each be provided with the same reference signs. The represented elements and their proportions among themselves are not to be regarded as true to scale. Rather, individual elements, such as layers, components, devices and regions, can be displayed excessively large for better displayability and/or better understanding.

FIG. 1 shows the chemical and physical properties of three inorganic fillers F1, F2 and F3 (generally F). In particular, the inorganic filler F is silicon dioxide. Preferably, the silicon dioxide is amorphous and has been fired. All three inorganic fillers F1 to F3 comprise the CAS numbers 60676-86-0. In particular, the degree of purity of silicon dioxide (amorphous, fired) is greater than 99.5%. The density ρ in g/ml is 2.2 g/ml for all three inorganic fillers. In particular, the inorganic fillers are shaped as particles, in particular the grain shape is spherical. The inorganic fillers F1 to F3 have a specific surface area A_{O} between 2.2 and 5.3 g/m². The inorganic fillers F1 to F3 have a d₅₀ value between 2.6 μm and 4.3 μm. The inorganic fillers F1 to F3 have an upper particle size value dₘₐₓ of at most 30 μm, in particular at most 16 μm or 12 μm.

The percentage shown in the table means, for example, that 99.4% of the particles of the inorganic filler F1 have a maximum upper grain size of 12 μm. Accordingly, 100% of the particles of inorganic filler F2 have a maximum upper grain size of 12 μm. Accordingly, 99.8% of the particles of the inorganic filler F3 have an upper grain size of 16 μm. The electrical conductivity κ of inorganic fillers F1 to F3 is between 3.1 and 6.6 μS/cm².

FIG. 2 shows two FTIR spectra of an epoxy resin system 1 and an epoxy resin system 2, the transmission T in percent as a function of the wave number \tilde{ν} in cm⁻¹. Epoxy resin system 1, abbreviated as EH1, has the following composition:

1. 85% by weight cycloaliphatic epoxy resin,
2. 10% by weight of epoxy phenol novolac,
3. 1% alcohol by weight,
4. 3% by weight polyvinyl butyrate, and
5. 1% by weight cationic accelerator.

Epoxy resin composition 2, abbreviated as EH2, has the following composition:

1. 95.5% by weight cycloaliphatic epoxy resin,
2. 1% by weight alcohol,
3. 2% by weight polyvinyl butyrate, and
4. 1.5% by weight cationic accelerator.

The FTIR spectrum for EH1 (2-1) and EH2 (2-2) shows that a band is observed at 1726 cm⁻¹. This band represents the cycloaliphatic epoxy resin. OH bands are also shown in the range greater than 3000 cm⁻¹.

FIG. 3 shows three FTIR spectra according to an embodiment. The transmission T is shown in percent % as a function of the wave number in cm⁻¹. The FTIR spectrum of the inorganic fillers F1 to F3 depicted in FIG. 1 is shown. The inorganic fillers F1 to F3 consisting of silicon dioxide were dried at 110° C. for 16 hours before processing and show no traces of moisture and no hydroxyl groups in the FTIR spectrum, as no characteristic oscillations in the range of 3400 cm⁻¹ or 1580 cm⁻¹ could be found.

FIG. 4 shows a DSC curve (DSC, Differential Scanning calorimetry) of the epoxy resin system EH2 with 75% by weight filler F3 according to an embodiment. The heat flow Q is shown as a function of the temperature T in ° C. From the DSC curves, the peak temperature T peak and the initial temperature T onset were determined in ° C. respectively. The peak temperature T-peak is the temperature at the minimum curve (4-1). The initial temperature T-Onset is extrapolated (4-2). The enthalpy ΔH in −J/g could be determined from the area of the DSC curve. The heating rate was 10 K/min.

FIG. 4B shows the DSC measurement results of EH1 and EH2, while the epoxy resin systems EH1 and EH2 have a different inorganic filler F1, F2 or F3 with the corresponding content m in % by weight. The mass m of the filler F mixed in was between 70 and 75% by weight. The reaction enthalpies ΔH vary between −152 J/g and −172 J/g depending on the filling level of the inorganic filler. The peak temperatures T-Peak vary between 125° C. and 144° C. depending on the filler content of the inorganic filler. The results are based on a unique heating up. A second DSC run shows no residual reaction. T_{g} is not resolved in the DSC, i.e. not detected on the graph.

FIGS. 5A and 5B show rheological measurements of the epoxy resin system EH1. FIG. 5A shows the viscosity η at 25° C. in Pas·s depending on the shear rate S in 1/s of three examples A1 to A3. Example A1 shows the epoxy resin system EH1 with 60% by weight inorganic filler F1. The example A2 shows the epoxy resin system EH1 with 65% by weight inorganic filler F1. The example A3 shows the epoxy resin system EH1 with 70% by weight filler F1.

FIG. 5B shows a table of shear rate S at corresponding temperature T in ° C. of the three examples A1 to A3. The table of FIG. 5B also shows the thixotropy index T_{I} of the three examples A1 to A3. FIG. 5A shows that at constant shear rate S the epoxy resin system EH1 with a higher inorganic filler content has a higher viscosity. The higher the shear rate, especially at shear rates >40 1/s, the content of inorganic filler F1 in the epoxy resin system EH1 has no significant influence on viscosity. The thixotropy index T_{I} at 25° C. increases from 2 in example A1 to 7.5 in example A3. The measurements were made with a plate cone (CP 25-2) at a constant shear rate. FIG. 5B also shows the temperature dependence of viscosity at a constant shear rate S of 5 1/s of the three examples A1 to A3. The higher the temperature, the lower the viscosity.

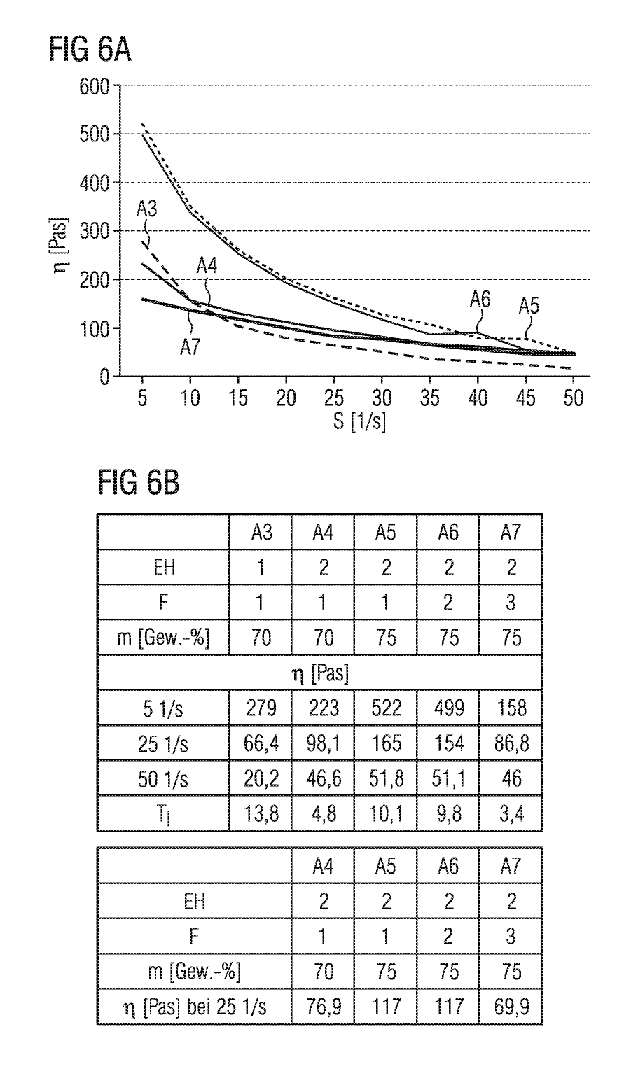

FIGS. 6A and 6B show rheological measurements of the epoxy resin systems EH1 and EH2 according to forms A3 to A7. A3 designates the same as in FIGS. 5A and 5B. A4 denotes here the epoxy resin system EH2 with an inorganic filler F1 with a proportion of 70% by weight. A5 here denotes the epoxy resin system EH2 with an inorganic filler F1 with a proportion of 70% by weight. A6 here denotes the epoxy resin system EH2 with an inorganic filler F2 with a content of 75% by weight. A7 here denotes the epoxy resin system EH2 with an inorganic filler F3 with a content of 75% by weight. The viscosity η was measured at 25° C. in Pas·s in 1/s as a function of the shear rate S. A plate cone (CP 25-2) was used.

FIG. 6B shows the respective experimental results. Example A3 shows a higher viscosity at 25 and 50 1/s compared to example A4. At a shear rate S of 5 1/s, the viscosity of A4 is lower than that of A3. The thixotropy index T_{I} of A3 is greater than T_{I} of A4 by a factor of 3. Examples A4 to A5 differ in their content of the inorganic filler F1. A higher content of inorganic filler F1 in the epoxy resin system EH2 leads to a higher thixotropy index T_{I}. In particular, the thixotropy index T_{I} is 2 times higher when the filler content is increased from 70 to 75% by weight.

Examples A5 to A7 show an identical epoxy resin system EH2 with different inorganic fillers F1 to F3, whereby the content of the filler in the examples A5 to A7 is constant and is 75% by weight. The table shows that the type of filler has an influence on the thixotropy index T_{I}. A7 with filler F3 has the lowest thixotropy index compared to design examples A5 and A6. Further the table in FIG. 6B also shows the viscosity at 25° C. with a constant shear rate S of 25 1/s of an epoxy resin system EH2 in which fillers 1 to 3 have been dispersed.

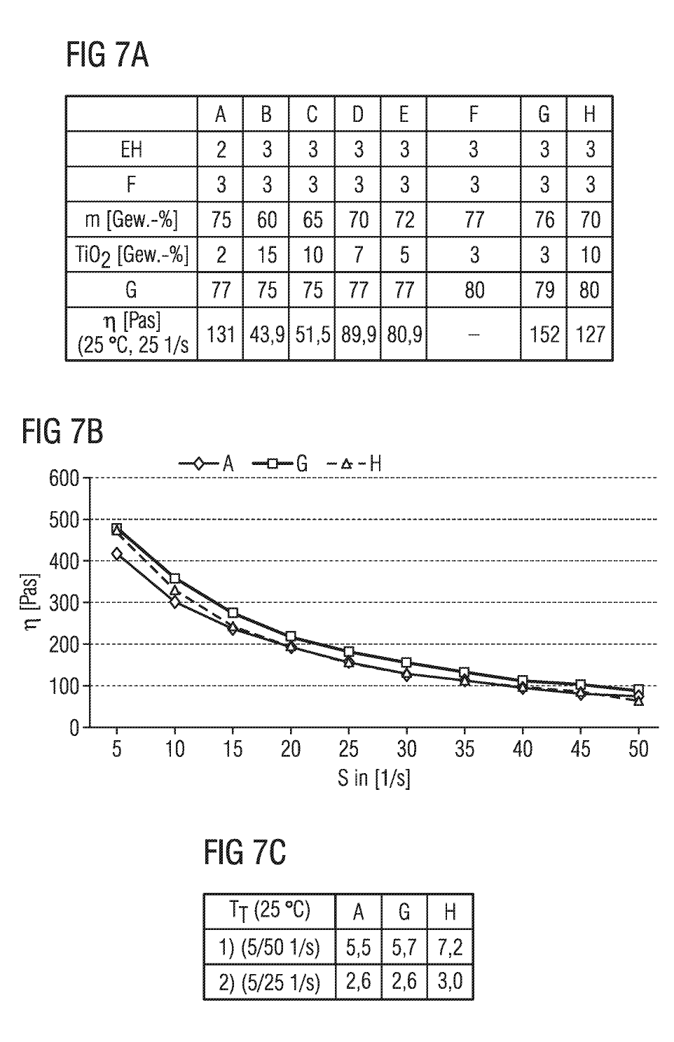

FIGS. 7A and 7B show rheological measurements of various design examples A to H. FIG. 7A shows epoxy resin systems EH2 and EH3, in which the filler F3 was introduced according to FIG. 1. The epoxy resin system EH2 has the composition shown in FIG. 2. The epoxy resin system EH3 has the following composition:

1. 96.8% by weight cycloaliphatic epoxy resin,
2. 1% by weight alcohol,
3. 1% by weight polyvinyl butyrate, and
4. 1.2% by weight cationic accelerator.

The filler content m in % by weight varies between 60% by weight and 77% by weight. In accordance with FIG. 7A, the examples A to H show different titanium dioxide contents TiO₂ between 2% by weight and 15% by weight. The total filling level G is between 75 and 80% by weight. Viscosity η in Pas/s at 25° C. with a shear rate S of 25 1/s is shown. FIG. 7B shows the shear rate dependence of the viscosity of pastes A, G and H. The viscosity was measured with a CP 25-2 plate cone. FIG. 7C shows the thixotropation T_{I} at 25° C. of paste A, G and H. FIGS. 7A to 7C show the rheological behavior of epoxy resin masses with different quartz fillers and TiO₂ contents and provide the expert with optimization tips during processing and the thermomechanical and optical molding material behavior. The viscosity of sample F is not shear stable.

FIGS. 8A and 8B show thermomechanical analyses (TMA) of various design examples. According to FIG. 8B, the epoxy resin system EH1 or EH2 was used. The inorganic filler F1, F2 or F3 was used as filler F in corresponding filler content m between 60 and 80% by weight. The CTE1 value was measured in ppm/K and the CTE2 value in ppm/K. FIG. 8A shows the dimension change DC in ppm as a function of the temperature T in ° C. of the epoxy resin system EH2 with 75% by weight of the filler F3. Using thermomechanical analysis, the expansion behavior of polymers is investigated and the linear thermal expansion coefficient below CTE1 and above CTE2 of the glass transition temperature in ppm/K at a specified heating rate here 3 K/min is determined. The inorganic filler reduces the coefficient of expansion, so that the thermal expansion behavior can be adapted to a wide range of requirements due to the filler content in the composite material.

FIGS. 9A and 9B show dynamic-mechanical analyses (DMA). FIG. 9A shows the storage module SM in MPa as a function of the temperature T in ° C. for the epoxy resin system EH2 with 75% by weight of an inorganic filler F1, F2 or F3. Curve 9-1 shows the epoxy resin system EH2 with 75% by weight of the inorganic filler F1, curve 9-2 with the inorganic filler F2 and curve 9-3 with the inorganic filler F3. FIG. 9A also shows tan δ as a function of the temperature T in ° C.

FIG. 9B shows the corresponding experimental values. The thermomechanical structural behavior of polymers is investigated by means of dynamic-mechanical analysis. The storage module and the tan δ as a ratio of storage and loss module as a function of temperature at a given heating rate and excitation frequency (here 3 K/min, 1 Hz, tension mode) are material characteristics which provide information on the thermomechanical usability of polymers in the target application, whereby tan δₘₐₓ (structural alpha transition) is considered as the glass transition temperature T_{g}. The curves in FIG. 9A and the experimental data in FIG. 9B show that the epoxy resin system has a high glass transition temperature T_{g}. In addition, the epoxy resin system has a high modulus of elasticity and high stiffness at temperatures >200° C.

FIG. 10 shows experimental data of a thermogravimetric analysis (TGA) of different epoxy resin systems according to an embodiment. The weight loss at certain temperatures according to a given temperature program, for example at 10 K/min in air, allows comparative conclusions on the temperature stability of polymers. In the present case, the weight losses GVT at 300° C. in percent are low and the temperature at 1% weight loss T_{GVT} in ° C. is above 320° C. Furthermore, it can be seen that filler types F1, F2 or F3 have no significant influence on the short-term temperature resistance.

FIG. 11 shows a compilation of experimental data of the epoxy resin system in the forms A, G and H as a white paste. The table shows the total filler level G in % by weight, the TMA results at 3 K/min, the CTE1 value in ppm/K, the CTE2 value in ppm/K, the DMA values (Tensile T, 1 Hz, 3K/min), i.e. the glass transition temperature T_{g}, the tan δₘₐₓ, the storage module SM in MPa at −40° C., 0° C., 20° C., 100° C., 200° C. and 260° C. and the TGA values at 10 K/min in air, especially the GVT, i.e. the weight loss at 300° C. in percent and the T_{GVT}, i.e. the temperature at 1% weight loss in ° C. After 3 days UVA exposure with 60 mW/cm² by surface emitters at around 90° C. and air, no yellowing or chalking was detected. The resin was cured for one hour at 120° C. and two hours at 160° C.

FIGS. 12A to 12D show optoelectronic devices 100 in various embodiments. In particular, the optoelectronic device has an epoxy resin system as described here.

According to FIG. 12A, optoelectronic device 100 has a lead-frame 1. Furthermore, the optoelectronic device has a carrier 5. A semiconductor layer sequence 2 is arranged on lead-frame 1. In particular, the semiconductor layer sequence 2 is set up to emit radiation. The semiconductor layer sequence 2 is arranged inside a recess 6 of a housing 3. The recess 6 can be filled with a casting 4. In addition, the casting may contain 4 additional particles, such as fluorescent particles (not shown here). The inventive epoxy resin system can also form or shape the housing. In particular, the housing has a wall thickness of ≥80 μm, especially ≥60 μm or ≥70 μm.

According to FIG. 12B, the epoxy resin system can also be designed as a substrate 7. A semiconductor layer sequence 2, for example an LED chip, can be arranged on substrate 7.

According to FIG. 12C, a semiconductor layer sequence 2 can be arranged on substrate 7. The semiconductor layer sequence 2 can be directly followed by a conversion element 8. Directly followed may in particular mean that no further layers or elements are arranged between the semiconductor layer sequence 2 and the conversion element 8. Alternatively, there may also be an adhesive layer between conversion element 8 and semiconductor layer sequence 2. The conversion element 8 can have the epoxy resin system or be formed from it. In addition, the epoxy resin system may contain fluorescent or converter particles.

FIG. 12D shows an optoelectronic device 100 according to an embodiment. According to FIG. 12D, a conversion element 8 is arranged both on the radiation exit surface of the semiconductor layer sequence 2 and on the side surfaces 2 of the semiconductor layer sequence 2.

The examples described in connection with the figures and the features thereof can also be combined with each other according to further examples, even if such combinations are not explicitly shown in the figures. Furthermore, the examples described in connection with the figures may have additional or alternative features according to the description in the general part.

The invention is not limited by the description based on the examples. Rather, the invention includes each new feature and each combination of features, which includes in particular each combination of features in the patent claims, even if this feature or this combination itself is not explicitly indicated in the patent claims or examples.

This patent application claims the priority of the German patent application 10 2016 102 685.9, the disclosure of which is hereby incorporated by reference.

### LIST OF REFERENCE NUMERALS

F filler
F1 filler 1
F2 filler 2
F3 filler 3
ρ density
A_{O} specific surface area
d₅₀ grain size
dₘₐₓ upper grain size or upper grain size value
κ electrical conductivity
EH epoxy resin
m content of filler
η viscosity
S Shear rate
T_{T} thixotropy index
T_{T} thixotropy
G total filling level
SM shear module
GVT weight loss at 300° C.
T_{GVT} temperature at 1% weight loss
1 lead-frame
2 semiconductor layer sequence
3 housing
4 casting
5 carrier
6 recess
7 substrate
8 conversion element
9 reflection element
100 optoelectronic device

1. Epoxy resin system comprising
at least one inorganic filler which has an upper grain size of at most 30 μm, which is an oxide or nitride of a metal or a semimetal,
at least one cycloaliphatic epoxy resin,
polyvinyl butyrate,
at least one cationic accelerator,
and wherein the epoxy resin system is a one-component system.

2. Epoxy resin system according to claim 1, wherein the polyvinyl butyrate comprises an average molecular weight of from 10000 g/mol to 80000 g/mol.

3. Epoxy resin system according claim 1, wherein the inorganic filler has a specific surface area of at least 2 g/m² and at most 20 g/m², a grain size value of at most 20 μm and an upper grain size of at most 30 μm.

4. Epoxy resin system according to claim 1, wherein the inorganic filler is selected from a group comprising silicon dioxide, titanium dioxide, aluminium oxide and zirconium oxide.

5. Epoxy resin system according to claim 1, which is free of anhydrides, free of silicones and/or free of siloxanes.

6. Epoxy resin system according to claim 1, which has a chlorine content of less than 100 ppm.

7. Epoxy resin system according to claim 1, wherein the inorganic filler has a content of between 50% by weight inclusive and 85% by weight inclusive, based on the total weight of the epoxy resin system.

8. Epoxy resin system according to claim 1, wherein the cycloaliphatic epoxy resin has a content of between 3% by weight inclusive and 50% by weight inclusive, based on the total weight of the epoxy resin system.

9. Epoxy resin system according to claim 1, wherein the polyvinyl butyrate has a content of between 0.1% by weight inclusive and 10% by weight inclusive, and the cationic accelerator has a content of between 0.1% by weight inclusive and 3% by weight inclusive, based in each case on the total weight of the epoxy resin system.

10. Epoxy resin system according to claim 1, which additionally comprises an alcohol and further epoxy resins, the content of the alcohol being between 0.1% by weight inclusive and 3% by weight inclusive, based on the total weight of the epoxy resin system.

11. Epoxy resin system according to claim 1, wherein the cationic accelerator is a thiolanium salt.

12. Epoxy resin system according to claim 1, which is storage stable at a temperature between 4° C. and 10° C.

13. Use of an epoxy resin system according to claim 1 for an optoelectronic device selected from the group consisting of a light emitting diode, a photodiode, a phototransistor, a photo-array, an optical coupler, an SMD device and an SMD-capable device.

14. Optoelectronic device comprising an epoxy resin system according to claim 1, wherein the epoxy, a reflection element, a casting, a conversion element and/or a substrate.

15. A process for producing an epoxy resin system according to claim 1 comprising the process steps:
A) providing a cycloaliphatic epoxy resin,
B) adding of polybutyl butyrate at a temperature between 50° C. and 80° C.,
C) adding a cationic accelerator at a maximum temperature of 45° C. to produce a matrix,
D) mixing the matrix produced according to step C) with at least one inorganic filler which is an oxide or nitride of a metal or semimetal, and
E) curing the mixture produced according to step D) at a temperature between 120° C. and 190° C.
